(19) United States
(12) Patent Application Publication
(10) Pub. No.: US 2011/0117680 A1
(43) Pub. Date: May 19, 2011

(54) INLINE DETECTION OF SUBSTRATE POSITIONING DURING PROCESSING

(75) Inventors: Vicky SVIDENKO, San Jose, CA (US); Mathew ABRAHAM, Mountain View, CA (US); Serkan KINCAL, Atherton, CA (US)

(73) Assignee: APPLIED MATERIALS, INC., Santa Clara, CA (US)

(21) Appl. No.: 12/948,089

(22) Filed: Nov. 17, 2010

Related U.S. Application Data
(60) Provisional application No. 61/261,907, filed on Nov. 17, 2009.

(51) Int. Cl. H01L 21/66

(52) U.S. Cl. 438/7; 257/E21.528

(57) ABSTRACT

Embodiments of the present invention generally provide a method for detecting the position of a substrate within a processing chamber. Embodiments of the present invention are particularly useful for the detection of a mis-positioned solar cell substrate during photoabsorber layer deposition processes within a solar cell production line. Reflected power is measured during processing of a substrate and communicated to a system controller. The system controller compares the measured reflected power with an established range of reflected power. If the measured reflected power is substantially out of range, the system controller signals for the chamber to be taken offline for inspection, maintenance, and/or repair. The system controller may further divert the flow of substrates within the production line around the offline chamber without shutting down the entire solar cell production line.

### CROSS-REFERENCE TO RELATED APPLICATIONS

This application claims benefit of U.S. Provisional Patent Application Ser. No. 61/261,907 (APPM/014619L), filed Nov. 17, 2009, which is herein incorporated by reference.

### BACKGROUND OF THE INVENTION

1. Field of the Invention

Embodiments of the present invention generally provide a method for detecting the position of a substrate within a processing chamber. Embodiments of the present invention are particularly useful for the detection of a mis-positioned solar cell substrate during photoabsorber layer deposition processes within a solar cell production line.

2. Description of the Related Art

Photovoltaic (PV) devices or solar cells are devices which convert sunlight into direct current (DC) electrical power. Typical thin film PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The back electrode may contain one or more conductive layers.

Conventional solar cell manufacturing processes are highly labor intensive and have numerous interruptions that can affect production line throughput, solar cell cost, and device yield. Additionally, significant downtime can be experienced due to problems associated with substrate positioning and routing within solar cell fabrication facilities. Therefore, a need exists for an automated solar cell production line capable of detecting the positioning of substrates during processing and adjusting the flow of substrates based thereon.

### SUMMARY OF THE INVENTION

In one embodiment, a method of processing a substrate comprises positioning the substrate in a processing chamber, depositing a layer of material on the surface of the substrate, measuring reflected radio frequency power while depositing the layer, comparing the measured reflected power to a baseline range of reflected power, and determining whether the measured reflected power is substantially outside of the baseline range.

In another embodiment, a method of fabricating a solar cell device comprises loading a substrate having a front contact layer deposited thereover into a solar cell production line, transferring the substrate into a first scribe module and removing at least a portion of the front contact layer, transferring the substrate into one of a plurality of chambers and depositing one or more photoabsorber layers over the front contact layer, determining whether the substrate is configured in an acceptable position while depositing the one or more photoabsorber layers over the front contact layer, and determining whether to take corrective action based on the determined position of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic, plan view of an example of a thin film solar cell device.

FIG. 1B is a schematic, cross-sectional view of a portion of the thin film solar cell device along section line A-A.

FIG. 2 illustrates a process sequence for forming a solar cell device using a solar cell production line according to one embodiment.

FIG. 3 is a plan view of the production line according to one embodiment.

FIG. 4A is a top schematic view of a processing system according to one embodiment.

FIG. 4B is a schematic cross-section view of a processing chamber according to one embodiment.

FIG. 5 depicts an exemplary plot of reflected power within a processing chamber versus time.

### DETAILED DESCRIPTION

Embodiments of the present invention generally provide a method for detecting the position of a substrate within a processing chamber. Embodiments of the present invention are particularly useful for the detection of a mis-positioned solar cell substrate during photoabsorber layer deposition processes within a solar cell production line. Reflected power is measured during processing of a substrate and communicated to a system controller. The system controller compares the measured reflected power with an established range of reflected power. If the measured reflected power is substantially out of range, the system controller signals for the chamber to be taken offline for inspection, maintenance, and/or repair. The system controller may further divert the flow of substrates within the production line around the offline chamber without shutting down the entire solar cell production line.

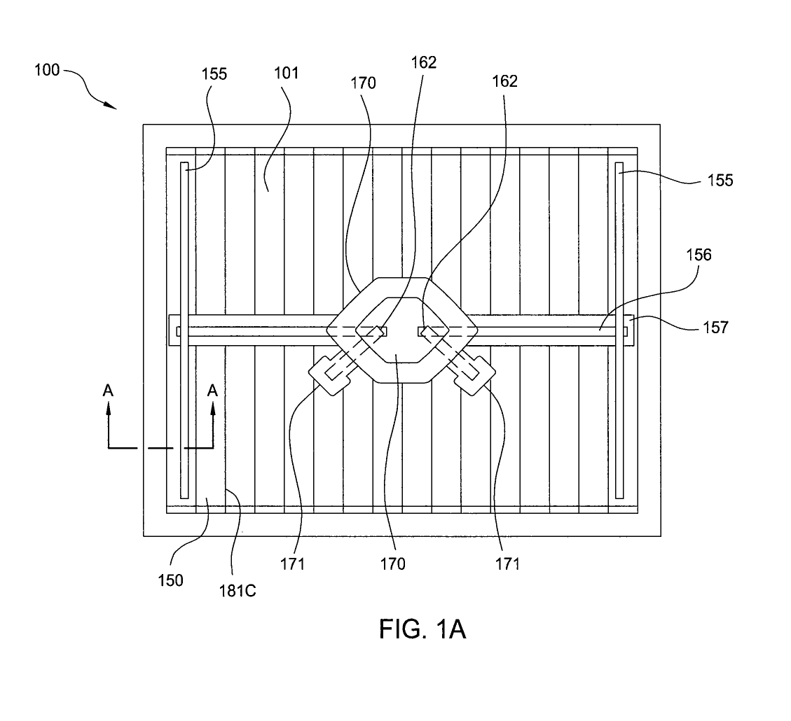

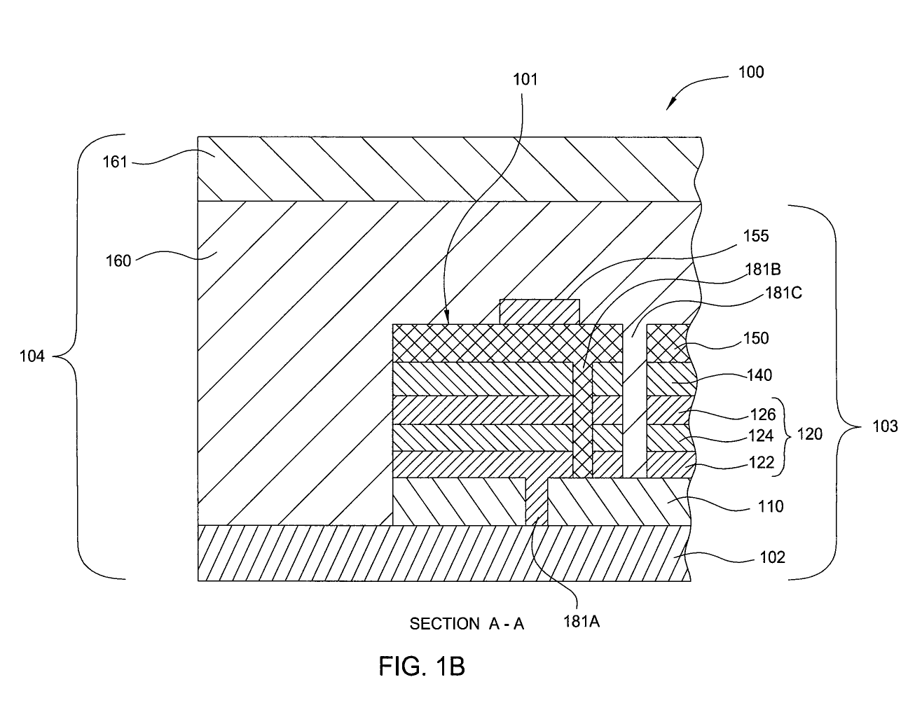

FIG. 1A is a schematic, plan view of an example of a thin film solar cell device 100. FIG. 1B is a schematic, cross-sectional view of a portion of the thin film solar cell device 100 along section line A-A. As shown in FIGS. 1A and 1B, the solar cell device 100 includes a substrate 102, such as a glass, polymer or metal substrate. The substrate 102 has a first transparent conducting oxide (TCO) layer 110 (e.g., zinc oxide (ZnO), tin oxide (SnO)) formed thereon. A p-i-n junction 120 is formed on the first TCO layer 110. In the example shown in FIG. 1B, a single p-i-n junction is shown; however, in other examples, p-i-n junction 120 may include multiple p-i-n junctions.

The p-i-n junction 120 includes a p-type amorphous silicon layer 122, an intrinsic type amorphous silicon layer 124 formed on the p-type amorphous silicon layer 122, and an n-type microcrystalline silicon layer 126 formed on the intrinsic type amorphous silicon layer 124. In one example, the p-type amorphous silicon layer 122 is formed to a thickness between about 60 Å and about 300 Å, the intrinsic type amorphous silicon layer 124 is formed to a thickness between about 1500 Å and about 3500 Å, and the n-type microcrystalline silicon layer 126 is formed to a thickness between about 100 Å and about 400 Å.

A second TCO layer 140 may be formed on the p-i-n junction 120, and a back contact layer 150 may be formed on the second TCO layer 140. The back contact layer 150 may include one or more of aluminum, silver, titanium, chromium, gold, copper, and platinum.

Trenches 181A, 181B, and 181C are formed in the layers (110, 120, 140, and 150), as shown, to divide the solar cell device 100 into a plurality of serially connected solar cells 101. Although formed together on the substrate 102, the individual solar cells 101 are isolated from each other by the trench 181C formed in the back contact layer 150, the second TCO layer 140, and the p-i-n junction 120. In addition, the trench 181B is formed in the p-i-n junction 120 prior to forming the back contact layer 150 so that the back contact layer 150 is in electrical contact with the first TCO layer 110.

An insulating strip 157, such as insulating tape, is applied across the back contact layer 150, and a cross buss 156 is applied on the insulating strip 157 as shown in FIG. 1A. Then, a side buss 155 is formed across the back contact layer 150 of the outermost solar cells 101 as shown. In one example, both the side buss 155 and cross buss 156 are metal strips, such as copper tape, nickel coated silver ribbon, silver coated nickel ribbon, tin coated copper ribbon, nickel coated copper ribbon, or the like. The side buss 155 is in direct electrical contact with the cross buss 156.

A bonding material 160 is applied to the module 100 and a back glass substrate 161 is positioned on the opposite side of the bonding material 160. The solar cell device 100 is then laminated to seal and protect the thin films and other internal components of the solar cell device 100. The bonding material 160 may be a sheet of polymeric material, such as polyvinyl Butyral (PVB) or ethylene vinyl acetate (EVA).

As shown in FIG. 1A, a hole is typically formed in the back glass substrate 161 prior to positioning it on the bonding material. The area of the hole within the solar cell device 100 remains at least partially uncovered by the bonding material 160 to allow the ends of the cross buss 156 to remain exposed through the hole. The end of each cross buss 156 has one or more leads 162 used to connect the cross buss 156 (and in turn, the side buss 155) to electrical connections 171 found in a junction box 170, which is sealed to the back glass substrate 161 and used to connect the solar cell device 100 to external electrical components.

To avoid confusion relating to the actions specifically performed on the substrates 102 in the processing sequences that follow, a substrate 102 having one or more of the deposited layers (e.g., reference numerals 110-150) and/or one or more internal electrical connections (e.g., side buss 155, cross-buss 156) disposed thereon is generally referred to as a device substrate 103. Similarly, a device substrate 103 that has been bonded to a back glass substrate 161 using a bonding material 160 is referred to as a composite solar cell structure 104.

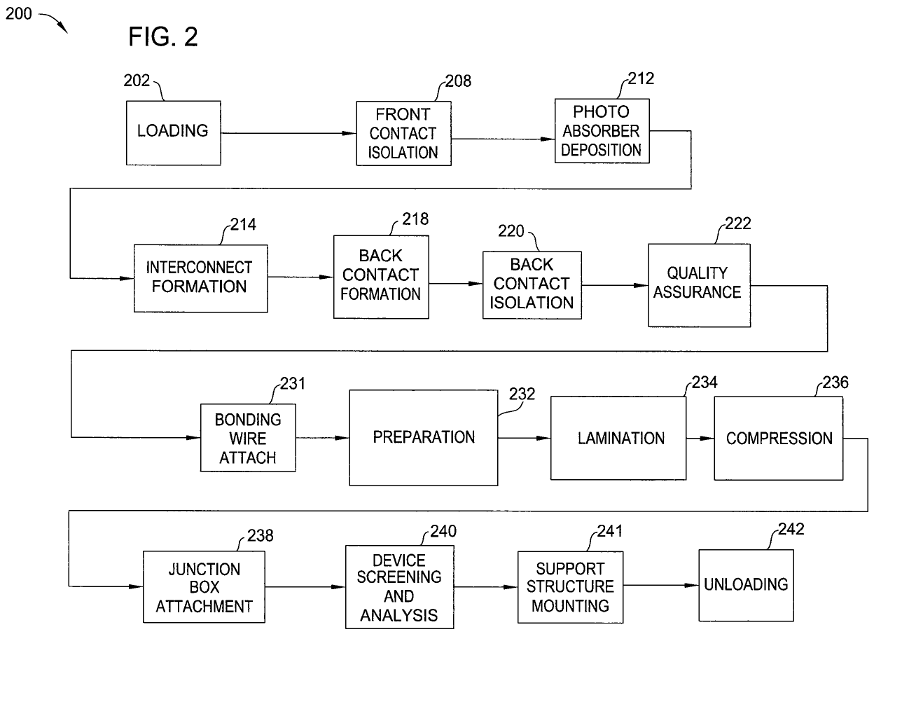

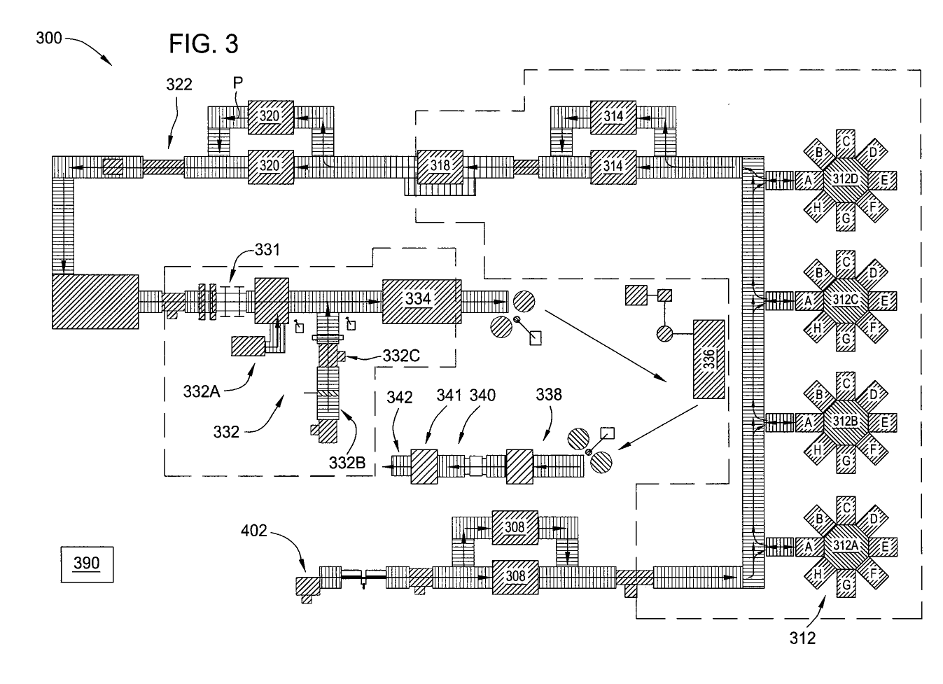

FIG. 2 illustrates a process sequence 200 for forming a solar cell device 100 using a solar cell production line 300. FIG. 3 is a plan view of the production line 300.

A system controller 390 may be used to control one or more components in the solar cell production line 300. The system controller 390 facilitates the control and automation of the overall solar cell production line 300 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, conveyors, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like.

A program (or computer instructions) readable by the system controller 390 determines which tasks are performable on a substrate. Preferably, the program is software readable by the system controller 390 that includes code to perform tasks relating to monitoring, moving, supporting, and/or positioning of a substrate along with various process recipe tasks and various chamber process recipe steps performed in the solar cell production line 300. The system controller 390 may also contain a plurality of programmable logic controllers (PLC's) that are used to locally control one or more modules in the solar cell production and a material handling system controller (e.g., PLC or standard computer) that deals with the higher level strategic moving, scheduling, and running of the complete solar cell production line. The system controller 390 may include a plurality of local controllers (i.e., CPU, memory, support circuits) contained within one or more of the processing modules within the production line 300 for local monitoring and control of the respective module and for communicating with a higher level controller within the system controller 390.

Referring to FIGS. 2 and 3, the process sequence 200 generally starts with a substrate loading process 202 in which a substrate 102 is loaded into a loading module 302 in the solar cell production line 300. In one example, substrates 102 already have a transparent conducting oxide (TCO) layer (e.g., first TCO layer 110) deposited on a surface of the substrate 102 to form a device substrate 103 before it is received into the system.

Next, the device substrate 103 is transported to a scribe module 308 in which a front contact isolation process 208 is performed on the device substrate 103 to electrically isolate different regions of the device substrate surface from each other. A laser scribe process may be performed to form the trenches 181A in the first TCO layer 110 of the device substrate 103.

Next, the device substrate 103 is transported to a processing module 312 in which one or more photoabsorber deposition processes 212 are performed on the device substrate 103. The one or more photoabsorber deposition processes 212 may include one or more preparation, etching, and/or material deposition processes to form the various regions of the solar cell device. Processes 212 generally include a series of sub-processing steps to form one or more p-i-n junctions 120. In general, the one or more sub-processing steps are performed in one or more cluster tools 312A-312D in the processing module 312 to form the one or more p-i-n junctions 120 on the device substrate 103. In cases where the solar cell device 100 includes multiple p-i-n junctions, the cluster tool 312A in the processing module 312 is adapted to form a first p-i-n junction and cluster tools 312B-312D are configured to form a second p-i-n junction.

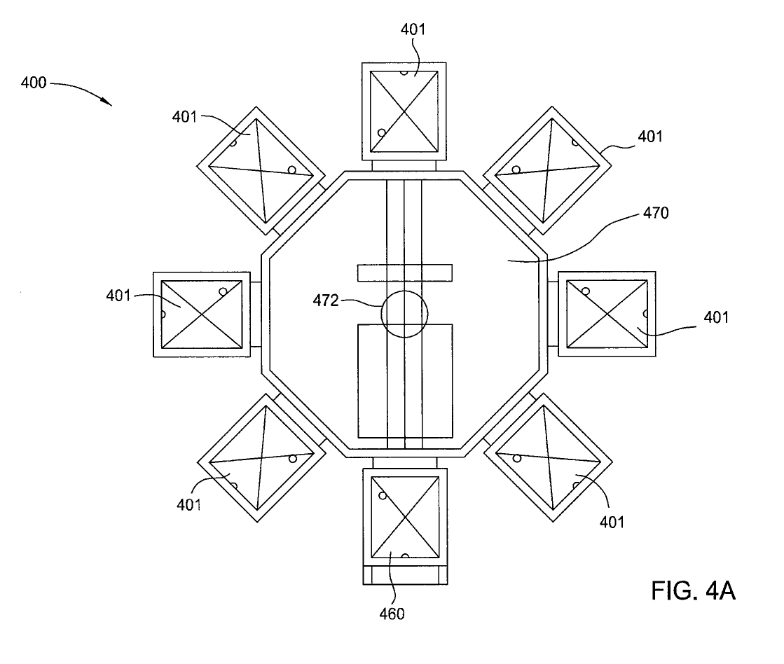

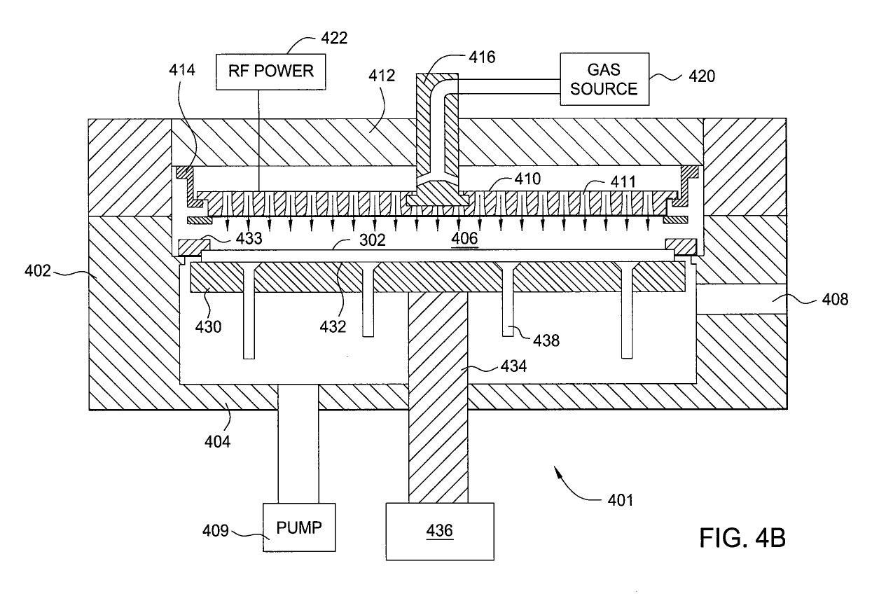

An example of a cluster tool and processing sequence used in the cluster tool, which can be used in the processing module 312, is further discussed below in conjunction with FIGS. 4A-4B.

Next, the device substrate 103 is transported to a scribe module 314 in an interconnect formation process 214 is performed on the device substrate 103 to form trenches 181B in the p-i-n-junction 120 of device substrate 103.

Next, the device substrate 103 is transported to a processing module 318 in which a back contact formation process 218 is performed on the device substrate 103. The substrate back contact formation process 218 may include one or more preparation, etching, and/or material deposition processes that are used to form the back contact layer 150.

Next, the device substrate 103 is transported to a scribe module 320 in which a back contact isolation process 220 is performed on the device substrate 103 to form trenches 181C in the back contact layer 150 and p-i-n junction 120 to electrically isolate the plurality of solar cells 101 from each other.

Next, the device substrate 103 is transported to a quality assurance module 322 in which quality assurance processes 222 are performed on the device substrate 103 to assure that the solar cells 101 meet a desired quality standard.

The device substrate 103 is next transported to a bonding wire attach module 331 in which a bonding wire attach process 231 is performed on the device substrate 103. In the bonding wire attach process 231, the cross buss 156 and the side buss 155 are attached to the device substrate 103 as shown in FIGS. 1A and 1B.

A bonding material 160 and back glass substrate 161 are prepared for delivery into the solar cell production line 300. A preparation process 232 is performed in a glass lay-up module 332, which comprises a material preparation module 332A, a glass loading module 332B, and a glass cleaning module 332C. The bonding material 160 is prepared in the material preparation module 332A, and then placed over the device substrate 103. The back glass substrate 161 is loaded into the loading module 332B, washed by the cleaning module 332C, and placed over the bonding material 160 on the device substrate 103.

Next, the device substrate 103, the back glass substrate 161, and the bonding material 160 are transported to a bonding module 334 in a lamination process 234 is performed to bond the back glass substrate 161 to the device substrate 103. The device substrate 103, the back glass substrate 161, and the bonding material 160 thus form a composite solar cell structure 104.

The composite solar cell structure 104 is then transported to an autoclave module 336 in which a compression process 236 is performed on the composite solar cell structure 104 to remove trapped gases that may be residing therein. In the compression process 236, the solar cell structure 104 is inserted in a processing region of the autoclave module 336 where heat and high pressure gases are delivered to reduce the amount of trapped gas and improve the properties of the bond between the device substrate 103, the back glass substrate 161, and bonding material 160.

Next, the composite solar cell structure 104 is transported to a junction box attachment module 338 in which a junction box attachment process 238 is performed. The junction box attachment module 338 is used to install a junction box 170 on the composite solar cell structure 104. The installed junction box 170 acts as an interface between the external electrical components that will connect to the solar cell device 100, such as other solar cells or a power grid, and the leads 162 of the cross buss 156 formed in the bonding wire attach process 231.

The solar cell structure 104 is then transported to a device testing module 340 in which device screening and analysis processes 240 are performed on the solar cell structure 104 to assure that the devices formed on the solar cell structure 104 meet desired quality standards. The device testing module 340 may include a solar simulator module that is used to qualify and test the output of the individual solar cells 101.

Next, the solar cell structure 104 is transported to a support structure module 341 in which support structure mounting processes 241 are performed to provide a complete solar cell device that has one or more mounting elements attached to the solar cell structure 104 so that the completed solar cell device 100 that can easily be mounted and rapidly installed.

The solar cell device 100 is then transported to an unload module 342 in which device unload steps 242 are performed to remove the solar cell device 100 from the solar cell production line 300.

### Photoabsorber Deposition Processing Module(s) and Processing Sequence

FIGS. 4A-4B illustrate a processing system 400 and a processing chamber 401 that may be used to form one or more p-i-n junctions 120 on the device substrate 103 discussed above. FIG. 4A is a top schematic view of one embodiment of a processing system 400, which may be one of the one or more cluster tools 312A-312D shown in the processing module 312 illustrated in FIG. 3. The processing system 400 can thus be used to perform one or more processes to form the various regions of the solar cell device 100. The processing system 400 generally includes a plurality of process chambers 481-487, such as a plasma enhanced chemical vapor deposition (PECVD) chamber, capable of depositing one or more desired layers on the device substrate 103. The process system 400 includes a transfer chamber 470 coupled to a load lock chamber 460 (e.g., reference “A” in cluster tools 312A-312D in FIG. 3) and the process chambers 401 (e.g., references “B”-“H” in cluster tools 312A-312D in FIG. 3). The load lock chamber 460 allows device substrates 103 to be transferred between the ambient environment outside the system and vacuum environment within the transfer chamber 470 and process chambers 401. The load lock chamber 460 includes one or more evacuatable regions for holding one or more device substrates 103. The evacuatable regions are pumped down during input of device substrates 103 into the system 400 and are vented during output of the device substrates 103 from the system 400. The transfer chamber 470 has at least one transfer robot 472 disposed therein that is adapted to transfer device substrates 103 between the load lock chamber 460 and the process chambers 401. While seven process chambers 401 are shown in FIG. 4A, the system 400 may have any suitable number of process chambers 401.

FIG. 4B is a schematic cross-section view of one embodiment of the processing chamber 401, such as a PECVD chamber, in which one or more films of a solar cell device 100 may be deposited. One suitable plasma enhanced chemical vapor deposition chamber is available from Applied Materials, Inc., located in Santa Clara, Calif. It is contemplated that other deposition chambers, such as hot wire chemical vapor deposition (HWCVD), low pressure chemical vapor deposition (LPCVD), physical vapor deposition (PVD), evaporation, or other similar devices, including those from other manufacturers, may be utilized to practice the present invention. The chamber 401 generally includes walls 402, a bottom 404, a showerhead 410, and a substrate support 430 which define a process volume 406. The process volume is accessed through a valve opening 408 such that a substrate, such as the device substrate 103, may be transferred into and out of the PECVD chamber 401. The substrate support 430 includes a substrate receiving surface 432 for supporting the device substrate 103 and a stem 434 coupled to a lift system 436 to raise and lower the substrate support 430. A shadow frame 433 may be optionally placed over a periphery of the device substrate 103 that may already have one or more layers formed thereon, for example, the TCO layer 110. Lift pins 438 are moveably disposed through the substrate support 430 to move the device substrate 103 to and from the substrate receiving surface 432.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the plurality of holes 411 in the showerhead 410 to the substrate receiving surface 432. A vacuum pump 409 is coupled to the PECVD chamber 401 to control the process volume 406 at a desired pressure. An RF power source 422 is coupled to the backing plate 412 and/or to the showerhead 410 to provide RF power to the showerhead 410 so that an electric field is created between the showerhead 410 and the substrate support 430. Plasma is generated from the gases in the electric field between the showerhead 410 and the substrate support 430. Various RF frequencies may be used, such as a frequency between about 0.3 MHz and about 200 MHz. Preferably, the RF power source is provided at a frequency of about 13.56 MHz. The RF power source 422 may also be provided at a frequency of about 40 MHz.

Referring back to FIG. 4A, one of the process chambers 401 may be configured to deposit a p-type silicon layer of the first p-i-n junction 120, another one of the process chambers 401 may be configured to deposit an intrinsic silicon layer of the p-i-n junction 120, and another of the process chambers 401 may be configured to deposit the n-type silicon layer of the p-i-n junction 120.

Alternatively, one of the process chambers 401 may be configured to deposit the p-type silicon layer of the p-i-n junction 120 while the remaining process chambers 401 are each configured to deposit both the intrinsic type silicon layer and the n-type silicon layer of the p-i-n junction 120. The intrinsic type silicon layer and the n-type silicon layer of the p-i-n junction 120 may be deposited in the same chamber without performing a passivation process, which is used to minimize cross-contamination between the deposited layers, in between the deposition steps.

It has been identified that mis-positioning of a device substrate 103 during deposition processes within a chamber 401 results in a solar cell device 100 having substantially lower efficiency as compared to a solar cell device 100 formed from a device substrate 103 that is properly positioned during processing. Such mis-positioning of the device substrate 103 may be caused by unexpected physical changes within the chamber 401, such as having one or more broken or seized lift pins 438 within the chamber 401. Other physical changes within the chamber 401, such as broken substrate material (e.g., glass), deposited materials, or other contamination, may also cause mis-positioning of the device substrate 103.

Conventional detection of mis-positioning of the device substrates 103 due to physical changes within the chamber 401 does not occur until the formed solar cell devices 100 are tested toward the end of the production line 300. By that time a significant number of device substrates 103 have been misprocessed in the defective chamber 401 and must be scrapped. Failure to rapidly detect the mis-positioning of the device substrates 103 can also cause damage to process chamber components, which results in significant system downtime to remove and replace the damaged components.

A correlation between the positioning of the device substrate 103 and the amount of reflected power measured within the chamber 401 has been developed in accordance with apparatus and processes described herein. For instance, substantially higher reflected power is measured during deposition processes when the device substrate 103 is mis-positioned due to a broken lift pin 438 or broken glass in the chamber 401 than when the device substrate 103 is properly positioned within the chamber 401.

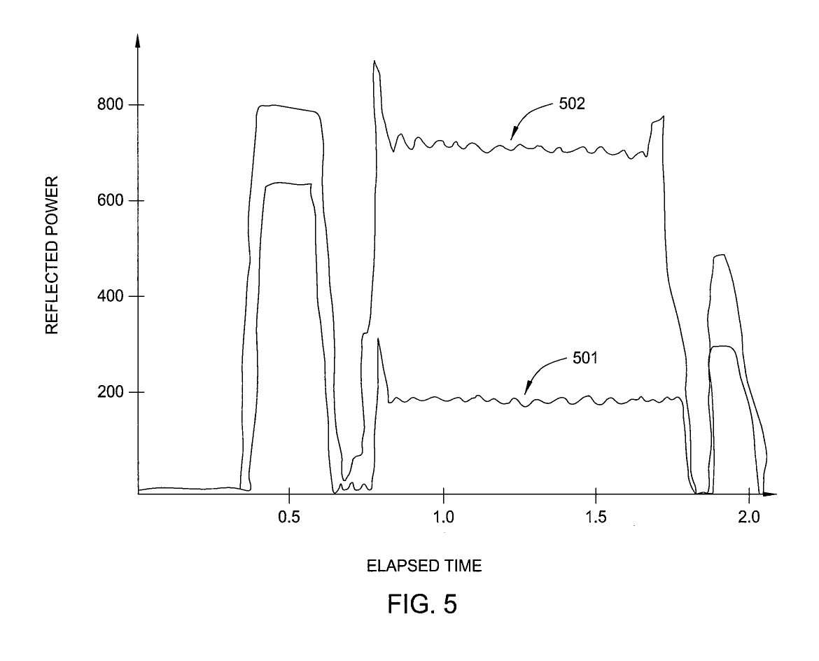

FIG. 5 depicts an exemplary plot of reflected power within the chamber 401 versus time during processing of a properly positioned device substrate 103 (curve 501) and a mis-positioned device substrate 103 (curve 502). In this example, reflected power measured during the deposition of one or more layers, such as the p-type silicon layer, on a mis-positioned device substrate 103 is over three times the amount of reflected power measured during deposition of the p-type silicon layer on a properly positioned device substrate 103.

Referring back to FIG. 4B, the RF power source 422 includes a control circuit that measures the reflected power from the interior of the chamber 401. The RF power source 422, including its control circuit, is in communication with the system controller 390. The system controller 390 is configured to monitor the reflected power measurement during deposition processes in each of the chambers 401 within the processing module 312. The system controller 390 is programmed to continuously compare the measured reflected power to an established baseline range. When the system controller 390 identifies that the reflected power measured in a particular chamber is substantially outside of the baseline range during processing, the system controller 390 may signal shutdown of the identified chamber 401 and divert the flow of device substrates 103 in the processing module 312 around the defective chamber 401. The defective chamber 401 may then be taken offline for maintenance and/or repair without shutting down the entire production line 300. Therefore, the system controller 390, in conjunction with the RF power source 422 of each chamber 401 within the processing module 312, is configured for inline detection of mis-positioned device substrates 103 within each chamber 401 during processing in order to detect physical alterations within the chamber 401, such as broken lift pins 438 or broken substrate material, that may lead to fabricating defective solar cell devices 100. This inline detection method allows quicker problem identification than conventional methods and results in significantly less downtime and fewer scrapped solar cell devices.

Referring to FIGS. 4A and 4B, in one example in which the substrate processing sequence is performed in the processing system 400, a device substrate 103 enters the processing system 400 through the load lock chamber 460. The device substrate 103 is then transferred by the vacuum robot 472 into the process chamber 401 that is configured to deposit a p-type silicon layer on the device substrate 103. During deposition, the system controller 390 monitors reflected power measured by the control circuit of the RF power source 422. If the measured reflected power exceeds an identified range, the system controller 390 sends signals to take the defective chamber offline for maintenance or repair and diverts the flow of subsequent device substrates 103 around the defective chamber.

After depositing the p-type layer in process chamber 401 the device substrate 103 is then transferred by the transfer robot 472 into the process chamber 401 that is configured to deposit both the intrinsic type silicon layer and the n-type silicon layer. During deposition, the system controller 390 monitors reflected power measured by the control circuit of the RF power source 422. If the measured reflected power exceeds an identified range, the system controller 390 sends signals to take the defective chamber offline for maintenance or repair and diverts the flow of subsequent device substrates 103 around the defective chamber. After depositing the intrinsic-type layer(s) and n-type layer(s) in process chamber 401 the device substrate 103 is returned to the load lock chamber 460 after which the device substrate 103 can be removed from the system.

It has also been found that the effectiveness of a processing chamber cleaning process, seasoning process, and/or general cleanliness of the processing chamber 401 can also be determined by monitoring the reflected power of a plasma enhanced chemical vapor deposition (PECVD) process. Processing chamber cleaning processes entail providing an etching fluid, such as an activated etching gas (e.g., NF₃ gas), to the processing chamber 401 for a period of time. Seasoning processes entail depositing a layer of material on the processing chamber walls to encapsulate any prior deposited material. As previously described, the system controller 390 is configured to monitor the reflected power measurement during deposition processes in each of the chambers 401 within the processing module 312. When the system controller 390 identifies that the reflected power measured in a particular chamber 401 is substantially outside of the baseline range during processing, the system controller 390 may signal shutdown of the identified chamber 401 and divert the flow of device substrates 103 in the processing module 312 around the defective chamber 401. Next, a technician may then inspect the identified “defective” chamber 401 to see if the cause of the high reflected power is caused by the positioning of the device substrate 103 in the chamber 401 or due to the state of cleanliness of the chamber 401. In one example, a technician may inspect the device substrate position or a device substrate transferring process through one or more view ports in the chamber 401 to see if any hardware related defects are affecting the position of the device substrate 103 in the chamber 401. If the high reflected power does not appear to be caused by the device substrate position, the system controller 390 may then perform one or more processes to affect the cleanliness or degree of seasoning of the chamber 401.

While the foregoing is directed to embodiments of the present invention, other and further embodiments of the invention may be devised without departing from the basic scope thereof, and the scope thereof is determined by the claims that follow.

1. A method of processing a substrate, comprising:
positioning the substrate in a processing chamber;
depositing a layer of material on the surface of the substrate;
measuring reflected radio frequency power while depositing the layer;
comparing the measured reflected power to a baseline range of reflected power; and
determining whether the measured reflected power is substantially outside of the baseline range.

2. The method of claim 1, wherein the baseline range of reflected power corresponds to acceptable positioning of the substrate during processing.

3. The method of claim 1, further comprising determining whether a hardware defect exists within the processing chamber if the measured reflected power is substantially outside of the baseline range.

4. The method of claim 3, further comprising cleaning the processing chamber if no hardware defect exists within the processing chamber.

5. The method of claim 4, further comprising seasoning the processing chamber if no hardware defect exists within the processing chamber.

6. The method of claim 1, further comprising halting the depositing the layer if the reflected power is determined to be substantially outside of the baseline range.

7. The method of claim 6, further comprising removing broken substrate material from the processing chamber if the reflected power is determined to be substantially outside of the baseline range.

8. The method of claim 6, further comprising servicing processing chamber hardware if the reflected power is determined to be substantially outside of the baseline range.

9. A method of fabricating a solar cell device, comprising:
loading a substrate having a front contact layer deposited thereover into a solar cell production line;
transferring the substrate into a first scribe module and removing at least a portion of the front contact layer;
transferring the substrate into one of a plurality of chambers and depositing one or more photoabsorber layers over the front contact layer;
determining whether the substrate is configured in an acceptable position while depositing the one or more photoabsorber layers over the front contact layer; and
determining whether to take corrective action based on the determined position of the substrate.

10. The method of claim 9, wherein determining whether the substrate is in an acceptable position, comprises:
measuring reflected radio frequency power during deposition processing of the substrate;
comparing the measured reflected power to a baseline range of reflected power; and
determining whether the measured reflected power is substantially outside of the baseline range, wherein the baseline range corresponds to the acceptable position.

11. The method of claim 10, wherein the corrective action comprises taking the chamber offline and diverting subsequent substrates to others of the plurality of chambers.

12. The method of claim 11, wherein the corrective action further comprises cleaning the chamber.

13. The method of claim 11, wherein the corrective action comprises servicing chamber hardware.

14. The method of claim 9, further comprising transferring the substrate into a second scribe module and removing at least a portion of the one or more photoabsorber layers.

15. The method of claim 14, further comprising:
transferring the substrate into a deposition module and depositing a conductive back contact layer over the one or more photoabsorber layers; and
transferring the substrate into a third scribe module and removing at least a portion of the back contact layer.

16. The method of claim 15, further comprising transferring the substrate into a bonding wire attach module and bonding two or more metal strips to a portion of the back contact layer.

17. The method of claim 16, further comprising transferring the substrate into a bonding module and laminating a polymeric material between the back contact layer and a back substrate.
